(19) United States
(12) Patent Application Publication
(10) Pub. No.: US 2026/0344363 A1
(43) Pub. Date: Oct. 29, 2026

(54) METHOD FOR TREATING A POLYCRYSTALLINE SILICON CARBIDE WAFER

(71) Applicant: Soitec, BERNIN (FR)

(72) Inventors: Walter Schwarzenbach, BERNIN (FR); Séverin Rouchier, BERNIN (FR); Sylvain Monnoye, Le Bourget-du-Lac (FR)

(21) Appl. No.: 19/106,098

(22) PCT Filed: Sep. 4, 2023
(86) PCT No.: PCT/FR2023/051332

§ 371 Date: Feb. 24, 2025

(30) Foreign Application Priority Data
Sep. 5, 2022 (FR) FR2208872

(51) Int. Cl. H10P 74/20; H10P 52/40

(52) U.S. Cl. CPC H10P 74/203; H10P 52/402

(57) ABSTRACT

A method for treating a polycrystalline silicon carbide wafer includes characterizing a surface condition of a front face of the polycrystalline silicon carbide wafer, and when the characterized surface condition does not meet a predetermined specification for the bonding of the polycrystalline silicon carbide wafer to a monocrystalline silicon carbide substrate with the front face at the bonding interface, correcting the surface condition of the front face of the polycrystalline silicon carbide wafer by removing material therefrom.

### CROSS-REFERENCE TO RELATED APPLICATIONS

This application is a national phase entry under 35 U.S.C. § 371 of International Patent Application PCT/FR2023/051332, filed Sep. 4, 2023, designating the United States of America and published as International Patent Publication WO 2024/052615 A1 on Mar. 14, 2024, which claims the benefit under Article 8 of the Patent Cooperation Treaty of French Patent Application Serial No. FR2208872, filed Sep. 5, 2022.

### TECHNICAL FIELD

The field of the present disclosure is that of polycrystalline silicon carbide wafers intended to act as supports for thin layers of single-crystal silicon carbide.

### BACKGROUND

Silicon carbide (SiC) is increasingly widely used in power electronics applications, in particular to meet the needs of growing ranges of electronics, such as, for example, electric vehicles. Power devices and integrated power-supply systems based on single-crystal SiC can actually manage a much higher power density than their conventional silicon counterparts, and do so with active regions of smaller size.

Nevertheless, the substrates made of single-crystal SiC intended for the microelectronics industry remain expensive and difficult to supply in large sizes. It is thus advantageous to resort to layer transfer solutions in order to produce composite structures typically comprising a thin layer made of single-crystal SiC on a lower cost support substrate. One well-known thin-layer transfer solution is the SMART CUT™ process. Such a process makes it possible, for example, to manufacture a composite structure comprising a thin layer made of single-crystal SiC, taken from a donor substrate made of single-crystal SiC, (m-SiC) in contact with a receiving substrate made of polycrystalline SiC (p-SiC).

This receiving substrate is a wafer of p-SiC obtained from a relatively thick slab of p-SiC (for example, from 0.6 to 3 mm in thickness). A deposition of p-SiC on a growth substrate (for example, a graphite substrate), typically a chemical vapor deposition at a temperature of between 1100° C. and 1400° C., makes it possible to form the p-SiC slab. Following the removal of the growth substrate, the p-SiC slab is subjected to a process of formation of one or more wafers (wafering process) which comprises various cleaning, etching, grinding and polishing stages and makes it possible to obtain one or more p-SiC wafers having a desired form (in particular a beveled edge) and a desired thickness. Sawing can also be carried out during this process, in particular when several wafers have to be manufactured from the one same slab. The thickness of the polycrystalline SiC wafer thus manufactured is, according to the SEMI standard, 350 μm+/−25 μm for a substrate of a diameter of 150 mm, or 500 μm+/−25 μm for a substrate of a diameter of 200 mm.

The SMART CUT™ process applied to the SiC requires the availability of a specific surface preparation before the donor substrate (mSiC) and receiving substrate (pSiC) can be bonded together, the bonding being able to be performed, for example, using the ADB (Atomic Diffusion Bonding) or the SAB (Surface Activation Bonding) technique. This surface preparation seeks to create a specific surface condition, characterized by its roughness, over a spatial frequency range extending from 5×5 μm to 150×150 μm.

However, this surface preparation does not appear to be perfectly repeatable since numerous p-SiC wafers prepared in this way are accompanied by a risk of incomplete transfer of the m-SiC layer during the SMART CUT™ process. Thus, in practice, the p-SiC wafers prepared in this way are sorted beforehand in order to reject those that do not meet the roughness specifications needed in order to meet the requirements of the bonding process. The reject rate proves to be high, while the p-SiC wafers have a high cost and the manufacturing thereof requires a great deal of energy.

### BRIEF SUMMARY

It is an objective of the present disclosure to reduce this reject rate in order to lower the cost of the SMART CUT™ process applied to the SiC, and the environmental impact thereof.

To this end, the present disclosure provides a method for processing a polycrystalline silicon carbide wafer, comprising the following steps:
characterizing a surface roughness of a front face of the polycrystalline silicon carbide wafer;
when the characterized surface roughness meets a predetermined specification for the bonding of the polycrystalline silicon carbide wafer to a single-crystal silicon carbide substrate with the front face at the bonding interface: performing the bonding;
when the characterized surface roughness does not meet the specification, reducing the surface roughness of the front face by removing a thickness of between 3 μm and 10 μm of material from the front face of the polycrystalline silicon carbide wafer; repeating the characterization of the surface roughness of the front face; and when the surface roughness characterized by repeating the characterization step meets the predetermined specification, performing the bonding.

The predetermined specification corresponds to a criterion determined beforehand as being sufficient, when met, to obtain, for example, complete bonding of the p-SiC wafer to the m-SiC substrate with the front face at the bonding interface. The bonding is the to be complete when the m-SiC substrate is bonded to the entirety of the front face with the exclusion of a peripheral ring of a width at all points less than 10 mm, preferably less than 6 mm, and more preferably still, less than 5 mm. The step of bonding and the step of removing material are alternatives governed, respectively, by compliance or non-compliance in the characterization of the surface roughness of the face that is to be bonded. Thus, the method according to the present disclosure makes it possible to identify, from among a batch of wafers originating from the one same wafering process, those polycrystalline silicon carbide wafers that carry a risk of incomplete transfer of a layer of single-crystal silicon carbide, so that these wafers can be corrected until the surface condition of the wafer will allow satisfactory bonding, so as to avoid rejecting a significant number of wafers.

Certain preferred but non-limiting aspects of this method are as follows:
the removal of material is performed only on the front face;
the removal of material from the front face involves grinding;
the grinding comprises a succession of rough grinding and fine grinding;
the rough grinding is performed with a grinding wheel with an abrasive grit size characterized by a mesh size of less than 5000;
the rough grinding removes a thickness of material of less than 10 μm;
the fine grinding is performed with a grinding wheel with an abrasive grit size characterized by a mesh size of more than 5000;
the fine grinding removes a thickness of material of less than 3 μm;
the removal of material from the front face further involves, after the grinding, a polishing of the front face;
the polishing is a chemical or chemical-mechanical polishing;
the polishing removes a thickness of material of less than 1 μm;
the method further comprises the prior formation of the polycrystalline silicon carbide wafer from a polycrystalline silicon carbide slab, the prior formation involving double-sided thinning (wafering) of the polycrystalline silicon carbide slab, the double-sided wafering comprising, for example, in succession, a coarse grinding, a rough grinding and a fine grinding;
the prior formation further comprises steps of sawing, etching and/or polishing the rear face and/or the front face of the polycrystalline silicon carbide slab;
the characterization of the surface condition of the front face of the polycrystalline silicon carbide wafer involves a light-scattering haze measurement;
it comprises, when the surface roughness characterized by repeating the characterization of the surface roughness of the front face does not meet the specification, an additional reduction, by the removal of material, of the surface roughness of the front face;
the polycrystalline silicon carbide wafer is initially supplied with an initial thickness within an interval of acceptable thicknesses and, after the surface roughness of the front face has been reduced, has a final thickness that is within the same interval of acceptable thicknesses.

The present disclosure extends to a method for creating a batch of polycrystalline silicon carbide wafers each having a final thickness within an interval of acceptable thicknesses and comprising:
supplying a set of polycrystalline silicon carbide wafers each having an initial thickness within the same interval of acceptable thicknesses;
for each of the wafers of the set, successively:
   characterizing the surface roughness of a front face of the wafer;
   when the characterized surface roughness meets a predetermined specification for the bonding of the wafer to a single-crystal silicon carbide substrate with the front face at the bonding interface, adding the wafer to the batch;
   when the characterized surface roughness does not meet the predetermined specification: reducing the roughness of the front face by removing a thickness of between 3 μm and 10 μm of material from the front face of the polycrystalline silicon carbide wafer; repeating the characterization of the surface roughness of the front face; and when the surface roughness characterized by repeating the characterization step meets the predetermined specification, adding the wafer to the batch.

Finally, the present disclosure extends to a method for producing a batch of multilayer structures, each multilayer structure comprising a thin layer of single-crystal silicon carbide deposited on a polycrystalline silicon carbide wafer, the method comprising, for each wafer of a batch of polycrystalline silicon carbide wafers formed as mentioned hereinabove, the bonding of a single-crystal silicon carbide substrate onto the front face of the polycrystalline silicon carbide wafer.

### BRIEF DESCRIPTION OF THE DRAWINGS

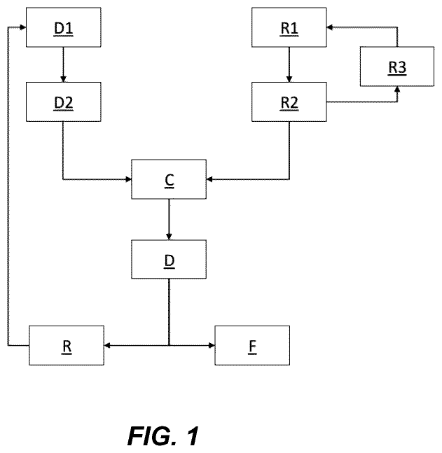

Other aspects, objects, advantages and features of the invention will become more apparent from reading the following detailed description of preferred embodiments thereof, which is given by way of nonlimiting example and made with reference to the attached drawings in which FIG. 1 is a diagram illustrating various steps of a SMART CUT™ process incorporating the processing of a p-SiC wafer in accordance with the present disclosure.

### DETAILED DESCRIPTION

The present disclosure relates to a method for processing a p-SiC wafer intended to act as a support for a thin layer of m-SiC. This method may comprise a prior step of forming the wafer from a p-SiC slab. In order to do this, the p-SiC slab is subjected to a wafering process. This process may notably involve double-sided thinning of the slab and possibly planarization of the slab in order to rectify any curvature it might exhibit. The thinning can be performed by grinding. This grinding may comprise a succession of coarse grinding, which reduces the thickness to around 400 μm, rough grinding, which reduces the thickness to around 360 μm, and fine grinding, which removes the last few microns of material. The different grinding operations differ in terms of the grit size of the grinding wheel used, these grit sizes becoming increasingly smaller through the succession of grinding operations. The various grinding operations are performed both on the front face and on the rear face of the polycrystalline silicon carbide slab.

In addition to the grinding, the wafering process may involve one or more steps of cleaning, etching and/or polishing the front face and/or the rear face of the polycrystalline silicon carbide slab. For example, the polishing involves a chemical-mechanical polishing. Polishing reduces the surface roughness of the polycrystalline silicon carbide slab and/or rectifies the flatness of the polycrystalline silicon carbide slab. Cleaning removes contamination.

Finally, the wafering process may involve sawing notably when several polycrystalline silicon carbide wafers are to be produced from the one same polycrystalline silicon carbide slab.

For example, the p-SiC slab is prepared by CVD onto graphite, which means that the double-sided thinning of the p-SiC slab is preceded by a step of detaching the graphite.

The polycrystalline silicon carbide wafer derived from the p-SiC slab preferably has an initial thickness within an interval of acceptable thicknesses or target thickness interval chosen so that once the surface roughness of the front face of the polycrystalline silicon carbide wafer has been reduced by one or more successive removals of material as described hereinafter, the final thickness of the p-SiC wafer is still within the same interval of acceptable values, the initial thickness and the final thickness referring to the mean thickness of the p-SiC wafer, respectively, before and after all of the removals of material.

More specifically, the initial thickness and the final thickness of the polycrystalline silicon carbide wafer fall within intervals respectively referred to as the initial thickness distribution and the final thickness distribution of the polycrystalline silicon carbide wafer. The initial thickness distribution of the polycrystalline silicon carbide wafer is chosen to be within the interval of acceptable thicknesses and the middle of the initial thickness distribution is chosen to be greater than the middle of the interval of acceptable thicknesses so that the final thickness distribution for the polycrystalline silicon carbide wafer is likewise within the interval of acceptable thicknesses, where the middle of each of the intervals refers to the mean of the lower and upper endpoints of the interval. For example, the middle of the initial thickness distribution is 15 μm greater than the middle of the interval of acceptable thicknesses.

Such an embodiment advantageously makes it possible to obtain polycrystalline silicon carbide wafers that conform to a thickness standard despite the implementation of one or more successive reductions of the surface roughness through the removal of material. The thickness standard may correspond to a range of thicknesses acceptable to a piece of semiconductor industry equipment. Alternatively or in addition, the thickness standard may either conform to a specification commonly adopted in the semiconductor industry, or be clearly defined by a semiconductor industry standard.

For example, the interval of acceptable thicknesses is that defined by the SEMI standard for p-SiC slabs of a diameter of 150 mm, namely 350 μm+/−25 μm. As a further example, the interval of acceptable thicknesses is that commonly adopted by most of the semiconductor industry for p-SiC slabs of a diameter of 200 mm, namely 500 μm+/−25 μm.

In that case, the wafer derived from the 150mm-diameter p-SiC slab may have an initial thickness within an initial thickness distribution that is offset toward 365 μm, for example, an initial thickness of 365 μm+/−10 μm and the wafer derived from the 200mm-diameter p-SiC slab may have an initial thickness within an initial thickness distribution that is offset toward 515 μm, for example, a thickness of 515 μm+/−10 μm. This embodiment allows the final thickness of the 150mm-diameter p-SiC wafer to remain compliant with the SEMI standard by having a final thickness within a final thickness distribution of 350 μm+/−25 μm, and allows the final thickness of the 200mm-diameter p-SiC wafer to remain compliant with the specification commonly adopted by the semiconductor industry by having a final thickness within a final thickness distribution of 500 μm+/−25 μm even though, in accordance with the present disclosure described hereinafter, one or more operations of correcting the surface condition of the p-SiC wafer are performed in order to ensure the successful outcome of the SMART CUT™ process after the wafer has been bonded to a substrate made of m-SiC.

As depicted in FIG. 1, the method according to the present disclosure may thus comprise a step R1 of supplying a p-SiC wafer. The method according to the present disclosure moreover comprises a step (designated as R2 in FIG. 1) that involves characterizing a surface condition of a front face of the p-SiC wafer, typically in characterizing a roughness of this front face. This characterization may notably involve a light-scattering haze measurement. Such a haze measurement allows the surface roughness of the front face of the p-SiC wafer to be characterized. This haze is derived from a method using the optical reflectivity properties of the surface to be characterized, and corresponds to an optical signal scattered by the surface, due to the microroughness thereof. The haze measurement may, for example, be performed using the KLA-Tencor SURFSCAN® SP1 or SPA2 inspection system or using the Lasertec SICA88 inspection system.

The method according to the present disclosure next comprises a step that involves determining whether or not the characterized surface roughness meets a predetermined specification.

In certain embodiments, the determined specification is a criterion determined beforehand as being sufficient, when met, to obtain complete bonding of the p-SiC wafer to the m-SiC substrate with the front face at the bonding interface. The bonding is said to be complete when the m-SiC substrate is bonded to the entirety of the front face with the exclusion of a peripheral ring of a width at all points less than 10 mm, preferably less than 6 mm, and more preferably still, less than 5 mm. It will in fact be recalled that because substrates generally have a bevel around their edge, the bonding of the m-SiC substrate and therefore the subsequent transfer of the thin layer of m-SiC, occur over the majority of the surface of the p-SiC wafer but not in a peripheral annulus extending from the edge of the wafer and the width of which is notably dependent on the geometry of the bevel.

The predetermined specification may relate to an indirect measurement of the surface roughness. In the possible embodiment whereby the characterization of the surface roughness involves a haze measurement, the predetermined specification may be that the measured level of haze has to be below a predetermined threshold, or in other words below a haze-level limit value previously determined as being a guarantee of successful bonding, i.e., notably a complete bonding as defined hereinabove.

If the characterized surface roughness meets the predetermined specification then the method according to the present disclosure continues with the bonding (designated by C in FIG. 1), for example, using the ADB technique, of the p-SiC wafer to a substrate made of m-SiC, the front face of the p-SiC wafer being at the bonding interface. According to the SMART CUT™ process the m-SiC substrate is then detached along a plane of weakness formed therein beforehand by ion implantation, so as to transfer a thin layer of m-SiC onto the p-SiC wafer and thus form a composite structure, this detachment (designated as D in FIG. 1) being brought about by a heat treatment, a mechanical action or a combination of these means. In this regard, FIG. 1 designates the supply of the m-SiC substrate as D1 and uses D2 to designate the ion implantation used to weaken it. At the end of the detachment D and of the transfer of the thin layer of m-SiC onto the p-SiC wafer there are performed, on the one hand, a finishing treatment (designated as F in FIG. 1) on the composite structure and, on the other hand, possible recycling R of the remains of the m-SiC substrate so that it can be reused.

If the surface condition of the front face does not meet the predetermined specification, the method according to the present disclosure comprises a step (designated as R3 in FIG. 1) of reducing the surface roughness of the front face of the p-SiC wafer by removing material from this front face. Unlike the previous double-sided thinning of the p-SiC slab, the removal of material can be performed only on the front face.

This removal of material from the front face removes a thickness of material of between 3 and 10 μm. It may be achieved by grinding the front face. As mentioned previously, the grinding of the p-SiC wafer may be performed here only on the front face that is intended to be bonded to the m-SiC substrate. This grinding of the front face only is rendered possible by the fact that the double-sided grinding performed previously during the wafering process was able to balance the stresses between the front and rear faces.

The grinding may comprise a succession of rough grinding and fine grinding. The rough grinding may be performed with a grinding wheel with an abrasive grit size characterized by a mesh size of less than 5000. The rough grinding preferably removes a thickness of material of less than 10 μm, for example, a thickness of 5 μm.

The fine grinding may, for its part, be performed with a grinding wheel with an abrasive grit size characterized by a mesh size of more than 5000, for example, a mesh size of between 8000 and 12000. The fine grinding preferably removes a thickness of material of less than 3 μm.

In one possible embodiment, the removal of material from the front face may further involve, after the grinding, a polishing of the front face. This polishing may be a chemical polishing or chemical-mechanical polishing. The polishing preferably removes a thickness of material of less than 1 μm.

It will be appreciated that, if this reduction in the surface roughness of the front face that is intended to be bonded is going to remove, for example, a thickness of 10 μm of material, then it is preferable for the p-SiC wafer to initially have a thickness greater than that expected by the standard, for example, a thickness of 365 μm, so that after correction, it will have the 350 μm thickness expected by the standard or else so that it can undergo several surface-condition corrective operations while maintaining a final thickness that is above the lower limit of 325 μm expected by the standard.

Specifically, following a first correction of the surface roughness of the front face intended to be bonding, the method comprises a repeat of the characterization of the surface condition of the front face and, when the surface condition characterized by the repeat characterization meets the predetermined specification, bonding is performed.

When the surface roughness characterized by repeating the characterization does not meet the predetermined specification, the method may comprise an additional reduction, by the removal of material, of the surface roughness of the front face.

The method according to the present disclosure may comprise one or more additional reductions, through the removal of material, of the surface roughness of the front face, each one preceded by a characterization of the surface condition. Each additional removal of material is preferably identical to the first removal of material. With 3 to 10 μm removed in each removal of material, a first removal of material and up to 3 additional removals of material may typically be accomplished while retaining a final thickness that conforms to the SEMI standard.

The method according to the present disclosure may moreover be repeated in order to process a set of wafers all derived from the one same wafering process, and create a batch of wafers each able to be bonded to a single-crystal SiC substrate despite the lack of repeatability of the surface condition of the wafers derived from the wafering process. Thus, the present disclosure extends to a method for creating a batch of polycrystalline silicon carbide wafers, comprising:
supplying a set of polycrystalline silicon carbide wafers;
for each of the wafers of the set:
   characterizing a surface roughness of a front face of the wafer;
   when the characterized surface roughness meets a predetermined specification for the bonding of the wafer to a single-crystal silicon carbide substrate with the front face at the bonding interface, adding the wafer to the batch;
   when the characterized surface roughness does not meet the predetermined specification, reducing the surface roughness of the front face by removing a thickness of between 3 μm and 10 μm of material from the front face of the polycrystalline silicon carbide wafer; repeating the characterization of the surface roughness of the front face; and then, when the surface roughness characterized by repeating the characterization step meets the predetermined specification, adding the wafer to the batch.

The wafers of the batch thus formed may then each be bonded to a single-crystal SiC substrate.

Each polycrystalline silicon carbide wafer of the set of polycrystalline silicon carbide wafers is preferably supplied with an initial thickness comprised in an interval of acceptable thicknesses and, after the surface roughness of the front face has been reduced, has a final thickness that is within the same interval of acceptable thicknesses.

In other words, each polycrystalline silicon carbide wafer derived from the method for creating the batch has a final thickness that is within a target range, each polycrystalline silicon carbide wafer of the set of polycrystalline silicon carbide wafers having been initially supplied with an initial thickness within a tight range encompassed within the target range, the tight range being centered on a value higher than the central value of the target range.

1. A method of treating a polycrystalline silicon carbide wafer, comprising the following steps:
characterizing the surface roughness of a front face of the polycrystalline silicon carbide wafer;
when the characterized surface roughness meets a predetermined specification for the bonding (C) of the polycrystalline silicon carbide wafer to a single-crystal silicon carbide substrate with the front face at the bonding interface: performing the bonding;
in response to the characterized surface roughness not meeting the specification, reducing the surface roughness of the front face by removing a thickness of between 3 μm and 10 μm of material from the front face of the polycrystalline silicon carbide wafer; repeating the characterization of the surface roughness of the front face; and in response to the surface roughness characterized by repeating the characterization step meeting the predetermined specification, performing the bonding.

2. The method of claim 1, wherein the removal of material is performed only on the front face.

3. The method of claim 1, wherein the removal of material from the front face involves grinding.

4. The method of claim 3, wherein the grinding comprises a succession of rough grinding and fine grinding.

5. The method of claim 4, wherein the rough grinding is performed with a grinding wheel with an abrasive grit size characterized by a mesh size of less than 5000.

6. The method of claim 4, wherein the rough grinding removes a thickness of material of less than 10 μm.

7. The method of claim 4, wherein the fine grinding is performed with a grinding wheel with an abrasive grit size characterized by a mesh size of more than 5000.

8. The method of claim 4, wherein the fine grinding removes a thickness of material of less than 3 μm.

9. The method of claim 4, wherein the removal of material from the front face further involves, after the grinding, a polishing of the front face.

10. The method of claim 9, in which the polishing is a chemical or chemical-mechanical polishing.

11. The method of claim 9, wherein the polishing removes a thickness of material of less than 1 μm.

12. The method of claim 1, further comprising the prior formation of the polycrystalline silicon carbide wafer from a polycrystalline silicon carbide slab, the prior formation involving double-sided thinning (wafering) of the polycrystalline silicon carbide slab, the double-sided wafering comprising, for example, in succession, a coarse grinding, a rough grinding and a fine grinding.

13. The method of claim 12, wherein the prior formation further comprises steps of sawing, etching and/or polishing the rear face and/or the front face of the polycrystalline silicon carbide slab.

14. The method of claim 1, wherein the characterization of the surface condition of the front face of the polycrystalline silicon carbide wafer involves a light-scattering haze measurement.

15. The method according to claim 1, comprising, when the surface roughness characterized by repeating the characterization of the surface roughness of the front face does not meet the specification, an additional reduction, by the removal of material, of the surface roughness of the front face.

16. The method according to claim 1, wherein the polycrystalline silicon carbide wafer is initially supplied with an initial thickness comprised in an interval of acceptable thicknesses and, after the surface roughness of the front face has been reduced, has a final thickness that is comprised within the same interval of acceptable thicknesses.

17. A method for creating a batch of polycrystalline silicon carbide wafers each having a final thickness comprised within an interval of acceptable thicknesses and comprising:
supplying a set of polycrystalline silicon carbide wafers each having an initial thickness comprised within the same interval of acceptable thicknesses;
for each of the wafers of the set, successively:
characterizing the surface roughness of a front face of the wafer;
when the characterized surface roughness meets a predetermined specification for the bonding of the wafer to a single-crystal silicon carbide substrate with the front face at the bonding interface, adding the wafer to the batch;
when the characterized surface roughness does not meet the predetermined specification: reducing the surface roughness of the front face by removing a thickness of between 3 μm and 10 μm of material from the front face of the polycrystalline silicon carbide wafer; repeating the characterization of the surface roughness of the front face; and when the surface roughness characterized by repeating the characterization step meets the predetermined specification, adding the wafer to the batch.

18. A method for creating a batch of polycrystalline silicon carbide wafers according to claim 17, wherein each silicon carbide wafer of the set of polycrystalline silicon carbide wafers is supplied with an initial thickness comprised within a tight range comprised within the interval of acceptable thicknesses, the tight range being centered on a value higher than the central value of the interval of acceptable thicknesses.

19. A method for producing a batch of multilayer structures, each multilayer structure comprising a thin layer of single-crystal silicon carbide deposited on a polycrystalline silicon carbide wafer, the method comprising, for each wafer of a batch of polycrystalline silicon carbide wafers formed in accordance with claim 18, the bonding of a single-crystal silicon carbide substrate onto the front face of the polycrystalline silicon carbide wafer.
